(19) United States
(12) Patent Application Publication
(10) Pub. No.: US 2024/0371928 A1
(43) Pub. Date: Nov. 7, 2024

(54) METHOD FOR PRODUCING A VERTICAL FIELD-EFFECT TRANSISTOR STRUCTURE AND CORRESPONDING VERTICAL FIELD-EFFECT TRANSISTOR STRUCTURE

(71) Applicant: Robert Bosch GmbH, Stuttgart (DE)

(72) Inventors: Daniel Krebs, Aufhausen (DE); Kevin Dannecker, Reutlingen (DE)

(21) Appl. No.: 18/648,577

(22) Filed: Apr. 29, 2024

(30) Foreign Application Priority Data
May 3, 2023 (DE) 10 2023 204 067.0
May 3, 2023 (DE) 10 2023 204 067.0

(51) Int. Cl. H01L 29/06; H01L 29/16; H01L 29/66; H01L 29/78

(52) U.S. Cl. CPC H01L 29/0634; H01L 29/0619; H01L 29/1608; H01L 29/66712; H01L 29/7802

(57) ABSTRACT

A vertical field-effect transistor structure. The vertical field-effect transistor structure has a semiconductor body having a first terminal zone, a drift zone, and a second terminal zone of a first conductivity type; a channel zone, arranged between the first and the second terminal zone, of the first or second conductivity type; a plurality of first trenches extending into the semiconductor body from the second terminal zone into the drift zone and form fins of the channel and second terminal zones; a control electrode arranged in the first trenches, which is arranged adjacent to the channel zone and insulated from the semiconductor body; a current path, connected between the first and the second terminal zone and in parallel with the channel zone, having at least one Schottky junction and being designed to conduct when a reverse voltage between the first and the second terminal zone is reached.

### FIELD

The present invention relates to a method for producing a vertical field-effect transistor structure and to a corresponding vertical field-effect transistor structure.

### BACKGROUND INFORMATION

Power MOSFETs with a vertical channel region (TMOSFETs) are typically used for the application of semiconductors with a wide band gap (e.g., silicon carbide (SiC) or gallium nitride (GaN)) in power electronics.

In the TMOSFET design, the n+ source region situated in a semiconductor material and the p channel region are interrupted by trenches that extend up to the n− drift region. Inside the trenches there is a gate electrode, which is separated from the semiconductor material by a gate oxide and is used to control the channel region.

By suitable selection of the geometry, epitaxial doping, channel doping, and screening doping, the switch-on resistance, threshold voltage, short-circuit resistance, oxide load, and breakdown voltage of such TMOSFETs can be optimized.

FIG. 4 shows a partial sectional view of an exemplary vertical field-effect transistor structure.

The field-effect transistor structure comprises a semiconductor body 100. A source electrode 80 contacts semiconductor fins FI separated by trenches G with a p-doped channel region 20, which fins have for this purpose an n⁺-doped source terminal region 30 in the upper region of the relevant fin FI. Next to the fins FI are arranged gate electrodes 40, which are separated from the fins FI and from the other regions by a gate dielectric 40a.

In the present case of a FinMOS, the p-doped channel regions 20 are introduced within the fins FI and adjacent to the gate electrodes 40, but in the case of a FinFET these regions can also have the same doping type as an n⁻ drift zone 12. In the region below the fins FI there are p⁺-doped shielding regions 90. These are electrically connected by the source electrode 80 via a contact metal region 10. The n⁻-doped drift zone 12, which merges into an n+-doped drain terminal region 14, extends below this. The n⁺-doped region drain terminal region 14 can be for example a substrate wafer, whereas the other regions are formed epitaxially. The n⁺-doped region drain terminal region 14 is electrically contacted via a drain electrode 9. Without applying a voltage to the gate electrodes 40, the corresponding field-effect transistor is not conductive. By applying a gate voltage to the gate electrode 40, a conductive channel is formed in the channel region 20 at the boundary to the gate dielectric 40a.

An important characteristic variable in such power transistors is the short-circuit strength. This describes how long or how well a component can withstand a short circuit, i.e., the full system voltage at the connected transistor, and how quickly it can then switch off. When switching off, it is essential that the space charge region under the fins FI forms quickly in the area between the p⁺-doped shielding regions 90 in order to thus shield the gate complex.

However, a space charge region based on a pn junction reacts relatively slowly due to the minority charge carriers present.

The present invention describes possible ways in which such a Schottky junction can help to improve the short-circuit strength and the switching behavior of the transistor in general.

### SUMMARY

The present invention provides a vertical field-effect transistor structure and a method for producing a vertical field-effect transistor structure.

Preferred example embodiments and developments of the present invention are disclosed herein.

An object of the present invention is to improve the short-circuit strength and generally the switching behavior of the transistor by means of a Schottky junction.

According to an example embodiment of the present invention, by inserting a Schottky contact at the base of the fins, the complex and expensive p⁺-doping of the shielding elements can be dispensed with. By suitably arranging the Schottky contact, the region under the fins can be depleted more quickly. This in turn is decisive for the short-circuit strength and the switching behavior.

According to a preferred development of the present invention, a particular terminal contact is provided on the highly conductive region and the region of the second conductivity type, and a contact metallization extends into the first trenches, which electrically connects the terminal contact and the second terminal zone.

According to a further preferred development of the present invention, a first superjunction region of the second conductivity type is arranged in the drift zone between the highly conductive region and the first terminal zone, which superjunction region electrically connects the highly conductive region to the first terminal zone.

According to a further preferred further development of the present invention, a second superjunction region of the second conductivity type is arranged in the drift zone between the region of the second conductivity type and the first terminal zone and electrically connects the region of the second conductivity type to the first terminal zone.

According to a further preferred development of the present invention, the drift region is formed from silicon carbide and the highly conductive region is formed from polysilicon.

### BRIEF DESCRIPTION OF THE DRAWINGS

Further features and advantages of the present invention are explained below with the aid of embodiments, with reference to the figures.

FIGS. 1A-1F are schematic partial cross-sectional views for explaining a method for producing a vertical field-effect transistor structure and a corresponding vertical field-effect transistor structure according to a first embodiment of the present invention.

FIG. 2 is a schematic partial cross-sectional view for explaining a vertical field-effect transistor structure according to a second embodiment of the present invention.

FIG. 3 is a schematic partial cross-sectional view for explaining a vertical field-effect transistor structure according to a third embodiment of the present invention.

FIG. 4 is a partial sectional view of an exemplary vertical field-effect transistor structure.

### DETAILED DESCRIPTION OF EXAMPLE EMBODIMENTS

In the figures, identical reference signs denote identical or functionally identical elements.

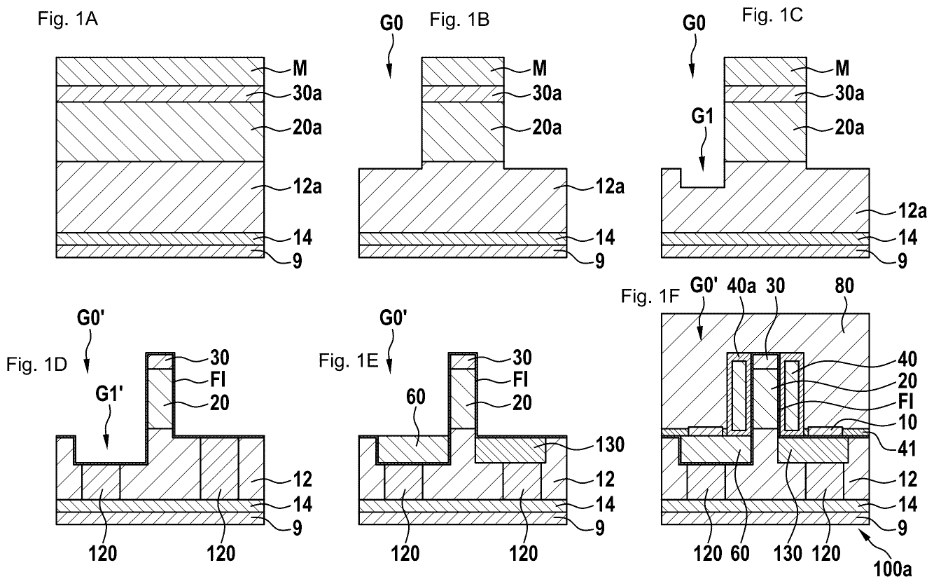

FIGS. 1A-1F are schematic partial cross-sectional views for explaining a method for producing a vertical field-effect transistor structure and a corresponding vertical field-effect transistor structure according to a first embodiment of the present invention.

With reference to FIG. 1A, an n⁺-doped substrate wafer 14, which comprises a metallization 9 on the back, is first provided for the semiconductor body 100a. The substrate wafer 14 forms the drain terminal region in the field-effect transistor structure and the metallization 9 forms the drain contact metallization. An n⁻-doped layer 12a, a p-doped layer 20a, an n⁺-doped layer 30a, and a mask layer M are epitaxially applied on the substrate wafer 14.

Further with reference to FIG. 1B, a mesa etching is carried out to form a precursor structure for the later fins, which is separated by trenches G0.

According to FIG. 1C, further trenches G1 are etched into the n⁻-doped layer 12a on the left-hand side of the precursor structure of the later fins. The depth of the trenches G1 and their later distance to the fin influences the effectiveness of the shielding and can be selected according to the component requirements. The right-hand side of the precursor structure remains protected by a mask (not shown).

As shown in FIG. 1D, in a further etching step after removing the mask layer M, the fins FI are formed by narrowing the precursor structure, wherein the trenches G0 and G1 are also widened and thus form first and second trenches G0′ and G1′ of the later vertical field-effect transistor structure. Optionally, a p-implantation step can now be performed to form p-doped regions 120 on the left-hand and right-hand side of the fin FI, which form superjunction regions.

Subsequently, the second trenches G1′ are each filled with a highly conductive p-region 60 which forms a Schottky junction to the drift region 12 on the left-hand side of the fin FI, as shown in FIG. 1E). For silicon carbide as semiconductor material of the drift region 12, CVD polysilicon is for example suitable for forming the Schottky junction.

On the other (right-hand) side of the fin FI, a p-doped region 130 is created by means of a p-implantation step. Alternatively, the p-implantation of the p-doped region 130 can take place before the deposition of the highly conductive region 60. The second trench G1′ is covered during the p-implantation of the p-doped region 130. Alternatively, the implantation of p-doped region 130 can occur before the etching of the second trench G1. The implanted material is then removed during the etching of the second trench G1 on the left-hand side of the precursor structure.

Finally, with reference to FIG. 1F, in each of the first trenches G0′ a control electrode 40 is formed which is arranged adjacent to the channel zone 20 and insulated from the semiconductor body 100a by a gate dielectric 40a.

On the drift region 12 with the highly conductive regions 60 on both sides of the fin FI, a further dielectric 41 is formed in which a relevant terminal contact 10 is provided for the corresponding highly conductive p-region 60 and the p-region 130.

Finally, a source contact metallization 80 is provided which contacts the source terminal region 30 and which extends into the first trenches G0′ so that it electrically connects the terminal contact 10 and the source terminal region 30.

In forward operation, the transistor works like an ordinary FinFET or FinMOS. Since the shielding p-doped region 130 is only present on one side of the fin FI, a wide space charge region corresponding to the pn junction is also only formed on this side. On the other side of the fin FI, however, a small space charge region corresponding to the Schottky junction between the highly conductive p-doped region 60 and the drift region 12 is formed, and the current has more space. This reduces the so-called JFET or spreading resistance. In the case of blockage, current is applied to the Schottky junction in the blocking direction, and a space charge region forms in the airflow area 12. This happens faster with a Schottky junction than is the case for a pn junction. In addition, between the drift region 12 and the p region 130, a space charge region forms which is wider corresponding to the pn junction. The gate dielectric 40a is therefore more effectively protected since it is quickly shielded by the rapidly forming space charge region of the Schottky junction at the beginning of switching off, and after a while, is protected by the effective shielding of the pn junction. This increases the breakthrough resistance and reliability of the component. The third operating case is reverse operation. In this case, the Schottky junction is polarized in the forward direction and the current flows through the Schottky junction. The reverse recovery behavior leads to lower voltage transients and lower overvoltages during commutation than for a pn junction.

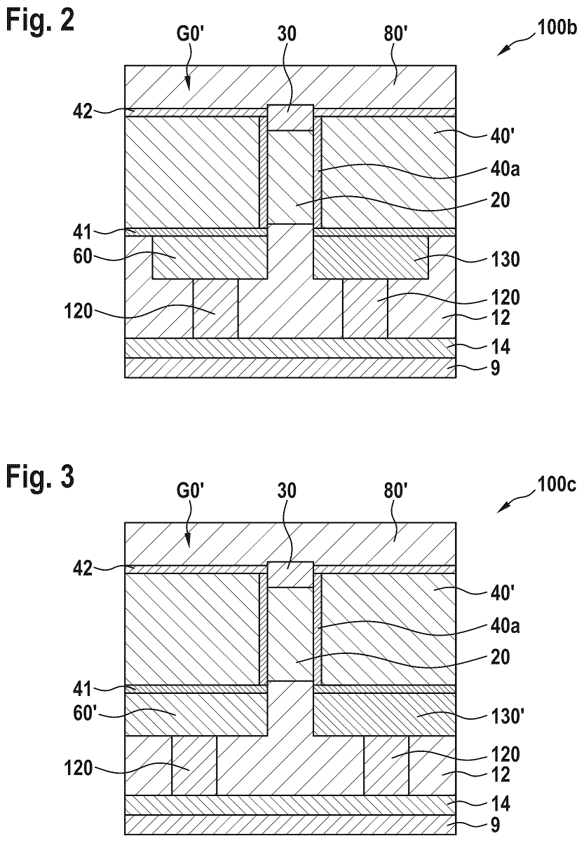

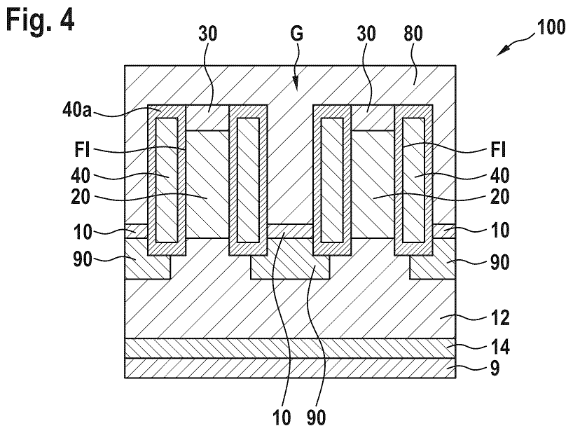

FIG. 2 is a schematic partial cross-sectional view for explaining a vertical field-effect transistor structure according to a second embodiment of the present invention.

While the first embodiment related to the case of application with a so-called split gate, the second embodiment relates to a stack gate.

The control electrodes 40′ of the semiconductor body 100b completely fill the first trenches G0″ and therefore completely cover the highly doped p-regions 60. The source contact metallization 80′ is electrically insulated from the control electrodes 40′ by a further dielectric 42.

In this embodiment, the highly doped p-regions 60 and the p-doped regions 130 are connected to the source contact metallization 80′ or to the source terminal region 30 by a corresponding electrical connection in the third dimension (not shown).

Otherwise, the second embodiment is constructed analogously to the first embodiment.

FIG. 3 is a schematic partial cross-sectional view for explaining a vertical field-effect transistor structure according to a third embodiment of the present invention.

The third embodiment also relates to the case of the stack gate. In contrast to the second embodiment, the highly doped p-regions 60′ and the p-doped region 130′ of the semiconductor body 100c completely fill the first trenches G0″ below the control electrodes 40′.

Otherwise, the third embodiment is constructed analogously to the second embodiment.

Although the present invention has been described on the basis of preferred exemplary embodiments, it is not limited thereto. In particular, the mentioned materials and topologies are only exemplary and not limited to the examples explained. The geometries shown are also only exemplary and can be varied as needed.

Although the highly conductive region has been described as a p-region in the above embodiments, it is not limited thereto, but can also be of the n-type or metallic as long as it forms a Schottky junction in the drift zone.

The Schottky junction and the pn junction can also be provided not only alternately, but in any order and frequency.

1-12. (canceled)

13. A vertical field-effect transistor structure, comprising:
a semiconductor body having a first terminal zone, a drift zone, and a second terminal zone of a first conductivity type;
a channel zone, arranged between the first and the second terminal zone, the channel zone being of the first conductivity type or of a second conductivity type complementary to the first conductivity type;
a plurality of first trenches extending into the semiconductor body, the first trenches extend from the second terminal zone into the drift zone and form fins of the channel zone and of the second terminal zone;
a control electrode arranged in the first trenches, the control electrode being arranged adjacent to the channel zone and insulated from the semiconductor body; and
a first current path connected between the first and the second terminal zone and in parallel with the channel zone, which first current path has at least one Schottky junction and is configured to conduct when a reverse voltage between the first and the second terminal zone is reached, wherein the Schottky junction is arranged in the drift zone and is formed between a highly conductive region buried in the drift zone and the drift zone, wherein the highly conductive region is electrically connected to the second terminal zone; and
a second current path connected between the first and the second terminal zone and in parallel with the channel zone, wherein the second current path has at least one pn junction and is configured to conduct when a reverse voltage between the first and the second terminal zone is reached;
wherein the pn junction is arranged in the drift zone and is formed between a region of the second conductivity type arranged in the drift zone and the drift zone, wherein the region of the second conductivity type is electrically connected to the second terminal zone.

14. The vertical field-effect transistor structure according to claim 13, wherein a specific terminal contact is provided on the highly conductive region and the region of the second conductivity type, and a contact metallization extends into the first trenches, which electrically connects the specific terminal contact and the second terminal zone.

15. The vertical field-effect transistor structure according to claim 13, wherein a superjunction region of the second conductivity type is arranged in the drift zone between the highly conductive region and the first terminal zone, wherein the superjunction region electrically connects the highly conductive region to the first terminal zone.

16. The vertical field-effect transistor structure according to claim 13, wherein a second superjunction region of the second conductivity type is arranged in the drift zone between the region of the second conductivity type and the first terminal zone, the second superjunction region electrically connects the region of the second conduction type to the first terminal zone.

17. The vertical field-effect transistor structure according to claim 13, wherein the drift region is formed of silicon carbide and the highly conductive region is formed of polysilicon.

18. A method for producing a vertical field-effect transistor structure, comprising the following steps:
providing a semiconductor body having a first terminal zone, a drift zone, and a second terminal zone of a first conductivity type;
forming a channel zone, arranged between the first and the second terminal zone, the channel zone being of the first conductivity type or of a second conductivity type complementary to the first conductivity type;
forming a plurality of first trenches extending into the semiconductor body, the first trenches extending from the second terminal zone into the drift zone and form fins of the channel zone and of the second terminal zone;
forming a control electrode arranged in the first trenches, which is arranged adjacent to the channel zone and insulated from the semiconductor body; and
forming a first current path connected between the first and the second terminal zone and in parallel with the channel zone, the first current path having at least one Schottky junction and is configured to conduct when a reverse voltage between the first and the second terminal zone is reached, wherein the Schottky junction is arranged in the drift zone and is formed between a highly conductive region buried in the drift zone and the drift zone, the highly conductive region being electrically connected to the second terminal zone; and
forming a second current path connected between the first and the second terminal zone and in parallel with the channel zone, the second current path has at least one pn junction and is configured to conduct when a reverse voltage between the first and the second terminal zone is reached;
wherein the pn junction is arranged in the drift zone and is formed between a region of the second line type arranged in the drift zone and the drift zone, wherein the region of the second line type is electrically connected to the second terminal zone.

19. The method for producing a vertical field-effect transistor structure according to claim 18, wherein a specific terminal contact is provided on the highly conductive region and the region of the second conductivity type, and a contact metallization is formed which extends into the first trenches and electrically connects the specific terminal contact and the second terminal zone.

20. The method for producing a vertical field-effect transistor structure according to claim 18, wherein a first superjunction region of the second conductivity type is arranged in the drift zone between the highly conductive region and the first terminal zone, the first superjunction region electrically connecting the highly conductive region to the first terminal zone.

21. The method for producing a vertical field-effect transistor structure according to claim 18, wherein a second superjunction region of the second conductivity type is arranged in the drift zone between the region of the second conductivity type and the first terminal zone, which second superjunction region electrically connects the region of the second conduction type to the first terminal zone.

22. The method for producing a vertical field-effect transistor structure according to claim 18, wherein the drift region is formed of silicon carbide and the highly conductive region is formed of polysilicon.

23. The method for producing a vertical field-effect transistor structure according to claim 18, wherein the highly conductive region is formed such that second trenches, which are filled with the highly conductive region, are formed in the drift region.

24. The method for producing a vertical field-effect transistor structure according to claim 23, wherein a first superjunction region of the second conductivity type is arranged in the drift zone between the highly conductive region and the first terminal zone, the first superjunction region electrically connecting the highly conductive region to the first terminal zone, wherein a second superjunction region of the second conductivity type is arranged in the drift zone between the region of the second conductivity type and the first terminal zone, which second superjunction region electrically connects the region of the second conduction type to the first terminal zone, and wherein the first and/or second superjunction region of the second conductivity type is formed before the filling of the second trenches by an implantation step directed into the second trenches.
